(19) United States
(12) Patent Application Publication
(10) Pub. No.: US 2025/0167057 A1
(43) Pub. Date: May 22, 2025

(54) Assemblage module 3D

(71) Applicant: COMMISSARIAT A L'ENERGIE ATOMIQUE ET AUX ENERGIES ALTERNATIVES, PARIS (FR)

(72) Inventors: Manon PORLAN, GRENOBLE (FR); Emmanuel MARCAULT, GRENOBLE (FR)

(21) Appl. No.: 18/920,494

(22) Filed: Oct. 18, 2024

(30) Foreign Application Priority Data
Oct. 18, 2023 (FR) 2311283

(51) Int. Cl. H01L 23/24; H01L 21/52; H01L 23/047; H01L 23/40; H01L 25/18

(52) U.S. Cl. CPC H01L 23/24; H01L 21/52; H01L 23/047; H01L 25/18; H01L 23/4006

(57) ABSTRACT

A power module incudes a first housing element (10) having a first cutout (12) for receiving a first chip (70; 70′; 70″), a first chip (70; 70′; 70″) at least partially received in the first cutout, having electrical contacts (71, 72, 73; 71′, 72′, 73′; 71″, 72″, 73″), and connection elements (41, 43, 45) electrically connected to the electrical contacts of the first chip. At least one insulating shim (90; 90′; 90″) is at least partially disposed in the first cutout so as to at least partially cover said chip, having at least one opening (91, 92; 91′, 92′; 91″, 92″) providing access to at least one electrical contact of the chip through the shim and/or at least one track (97″) ensuring the connection to one of the connection elements and/or a capacitor.

### RELATED APPLICATION

This application claims the benefit of French Patent Application No. 23 11283, filed on Oct. 18, 2023, the entirety of which is incorporated by reference.

### FIELD OF THE INVENTION

The present invention relates to semiconductor power modules and to a method for manufacturing them.

### PRIOR ART

Power modules generally comprise at least two electronic chips which are electrically connected to connection elements such as metal tabs, and can also comprise one or more capacitors which are electrically connected to the chips or to the connection elements.

Examples of power modules are disclosed in the publications FR3115651, WO2018/024973 and U.S. Pat. No. 9,041,183.

In the application WO2018/024973,
the chips are received in cutouts of suitable shape in a support.

Existing power modules are developed specifically for particular chips and take account of the size of the chip and of the location of the electrical contacts. Thus, some comprise screen-printed electrical tracks which are dependent on the arrangement of these contacts.

A drawback of these modules is the impossibility of using chips other than those for which the module has been developed, without having to extensively review the manufacturing method, notably the screen printing steps and/or the shape of the supports receiving the chips.

However, module manufacturers are sometimes faced with supply difficulties which force a change in chip suppliers, and the redesign of the manufacturing method when there is a change in chip model and the use of a new model which does not have the same dimensions and/or arrangements of contacts generates significant manufacturing delays and significant additional costs.

### DISCLOSURE OF THE INVENTION

Consequently, there is a need to overcome this drawback.

### SUMMARY OF THE INVENTION

The invention aims to meet this need, and it does so, according to one of its aspects, by proposing a power module comprising:
a first housing element having a first cutout for receiving a first chip,
a first chip at least partially received in the first cutout, having electrical contacts,
connection elements electrically connected to the electrical contacts of the first chip,
at least one insulating shim at least partially disposed in the first cutout so as to at least partially cover said chip, having at least one opening providing access to at least one electrical contact of the chip through the shim and/or at least one track ensuring the connection to one of the connection elements and/or a potential capacitor.

By virtue of the invention, it is possible to use a plurality of chips having different dimensions and/or arrangements of contacts, whilst limiting the changes to be applied to the module when switching from one chip model to another.

Specifically, different shims can be used depending on the chips in order to render said chips compatible with a large part of the elements making up the module, and these elements can thus remain unchanged.

This greatly simplifies the replacement of one chip with another, since it is no longer necessary, as in the prior art, to extensively review the manufacturing method.

Thus, in preferred exemplary implementations of the invention, the shim is the only element that needs to be modified to enable the use of a different chip on an existing module.

The module may comprise:
a second housing element having a second cutout for receiving a second chip,
a third housing element disposed between the first and second housing elements, notably having at least a third cutout for receiving a capacitor,
a second chip at least partially received in the second cutout, having electrical contacts,
connection elements electrically connected to the electrical contacts of the second chip,
at least one capacitor at least partially received in the third cutout and electrically connected to at least one of the chips and/or to the connection elements.

### Shim

The shim may be produced without any conductive element such as an electrical track or, as a variant, with at least one such conductive element.

The shim may be made of any suitable material, notably ceramic or other, its shape being obtained by sintering, 3D printing, machining or otherwise.

The shim already exists during its introduction into the corresponding cutout of the module.

The shape of the shim is dependent on the chip model associated therewith.

In examples, the shim has, at an edge, at least one lateral opening into which a corresponding connection element electrically connected to a contact of the chip engages. This connection element is, for example, a metal electrical connection tab, of flattened cross section.

In examples, the shim has, at two opposite longitudinal edges, two respective lateral openings into which two corresponding connection elements electrically connected to two respective contacts of the chip engage. These connection elements are, for example, metal tabs extending in directions away from the power module. They are, for example, contacts corresponding to power terminals of a transistor, such as the source or the drain.

The connection element or elements may be soldered to the corresponding contact(s) of the chip by any means, for example with the aid of soldering paste disposed at the interface between the components to be soldered together.

The shim may have, at an edge substantially perpendicular to the aforementioned longitudinal edges, an additional opening into which an additional connection element electrically connected to a respective contact of the chip engages. This is, for example, a contact corresponding to a control terminal, for example a gate contact of a power transistor.

This additional connection element may be soldered directly to a corresponding contact of the chip, or, as a variant, the shim bears an electrical track soldered to a corresponding contact of the chip and the additional connection element is soldered to the track.

The first cutout which receives the chip may have a contour of rectangular or other shape; however, the rectangular shape is preferred.

The chip may not occupy the entire cutout in question in top view.

When the chip occupies the entire cutout in top view, the cutout can allow the chip to be positioned therein, to within an assembly clearance. In this case, the shim can just be superposed with the chip without being interposed between said chip and one or more edges of the cutout. The shim may then have only the function of thickness compensation, assisting the positioning of the connection elements and potentially also serving to establish an electrical connection between a contact of the chip and a connection element which is not directly superposed therewith.

By contrast, when the chip does not occupy the entire cutout in top view, the shim advantageously helps to position said chip in the cutout by being inserted between said chip and at least one edge of the cutout.

Thus, in embodiment examples, the shim is longer than the chip at the contact thereof, and has at least one portion engaged into the cutout between the chip and the housing element defining the cutout receiving the chip. The shim is interposed, for example, on at least three sides, notably four sides, between the chip and the housing element defining the cutout receiving the chip.

The shim may have a face that is substantially coplanar with a face of the housing element defining the cutout receiving the chip in contact with the shim.

### Other Features

The third housing element may have cutouts for receiving connection elements positioned so as to make it possible to superpose the latter with electrical contacts of the second chip.

The housing elements may be passed through by holes allowing the passage of retaining members for retaining the housing elements in the assembled state, notably screws.

The module may comprise at least one heat transfer element in contact with an outer face of a chip, even better two heat transfer elements each in contact with an outer face of a respective chip, this or these heat transfer elements preferably each comprising a plate of metal, preferably of copper.

### Array of Modules

A further subject of the invention is an array of power modules, comprising at least a first and a second module according to the invention, at least one of the chips of the first module being different from a corresponding chip of the other module, the two modules comprising different shims and at least identical first and second housing elements. “Different chip” should be understood to mean that the chip model is different, by at least one of the dimensions thereof, notably length and/or width, and/or the arrangement of the contacts.

The connection elements may be identical, and also the third housing element.

### Manufacturing Method

A further subject of the invention is a method for manufacturing a power module, notably a module according to the invention, as defined above, this module comprising:
a lower housing element having a first cutout for receiving a first chip,
a first chip at least partially received in the first cutout, having electrical contacts,
   the method comprising the step consisting in:
covering the chip present in the first cutout with an insulating shim, this shim defining at least one opening which is superposed with at least one electrical contact of the chip or having an electrical track to be connected to an electrical contact of the chip, notably a track leading to an opening in the shim that is intended to receive a connection element.
   In such a method, the shim can help with the positioning of one or more connection elements relative to the chip and with the positioning of the chip in the cutout, notably when the latter is larger than the chip in top view and said shim is interposed between at least one edge of the cutout and the chip, the shim being selected from among a plurality of pre-existing shims depending on the type of chip used, all of these shims being adapted to be positioned in the cutout of the lower housing element.
   The shims are, for example, selected from among a set of shims comprising:
a shim, of preferably substantially constant thickness, having two opposite openings on its long sides and one opening on a short side, the dimensions of the shim corresponding substantially to those of the cutout of the first housing element,
a shim having two opposite openings on its long sides and one opening on a short side, the dimensions of the shim corresponding substantially to those of the cutout of the first housing element, the shim having, on its face facing towards the chip, opposite lateral returns intended to each be interposed between a long side of the chip and a corresponding edge of the first cutout, and at least one end tab intended to be interposed between a short side of the chip and a corresponding edge of the first cutout, and at least one portion intended to engage into the cutout between the chip and the lower housing element, on the opposite side from the end tab;
a shim having two opposite openings on its long sides and one opening on a short side, the dimensions of the shim corresponding substantially to those of the cutout of the first housing element, the shim having at least two portions each intended to be interposed between a short side of the shim and a corresponding edge of the cutout, the shim having, on its face facing towards the chip, opposite lateral returns intended to each be interposed between a long side of the chip and a corresponding edge of the first cutout, the shim also having at least one conductive track arranged to be at least partially superposed with a contact of the chip and with a connection element.

The aforementioned openings in each shim may be in the form of notches.

In an exemplary implementation of the invention, the method comprises the introduction:
of an upper housing element having a second cutout for receiving a second chip,
of an intermediate housing element disposed between the upper and lower elements,
of a second chip at least partially received in the second cutout, having electrical contacts,
of connection elements electrically connected to the electrical contacts of the chips,
of at least one capacitor electrically connected to at least one of the chips and/or to the connection elements.
   The method advantageously comprises the use of an assembly guide having at least a main cutout adapted to receive at least the lower housing element. This assembly guide preferably has secondary cutouts adapted to receive the connection elements.
   The main cutout may have a bottom comprising at least one impression for receiving a nut or a screw head, and the method may comprise the positioning of at least one nut or a screw head in the main cutout before the lower housing element, in particular, is introduced into said main cutout.
   The method may comprise the positioning of a heat transfer element, notably a metal, preferably copper, plate in the bottom of the main cutout.
   In an exemplary implementation, the method comprises the following successive steps:
the optional introduction, in the main cutout of the assembly guide, of nuts into the corresponding cutouts potentially provided at the bottom of said main cutout,
the introduction of a heat transfer element, preferably in the form of a metal plate, into the main cutout, covering the nuts where appropriate,
the introduction of the lower housing element onto the metal transfer element,
the introduction of the first chip into the cutout defined by the first housing element,
the introduction of the shim onto the first chip,
the introduction of connection elements that come to cover at least one contact of the chip and/or a track to be electrically connected to a contact of the chip,
the introduction of the intermediate housing element,
the introduction of the capacitor onto one of the connection elements, notably in a corresponding cutout of the intermediate housing element, this capacitor having a first electrical contact facing the connection element on which it is deposited,
the introduction of at least one other connection element extending at least partially facing a second electrical contact of the capacitor,
the introduction of the upper housing element onto the assembly present in the main cutout of the assembly guide,
the introduction of the second chip into the cutout of the upper housing element,
the introduction of a second heat transfer element, notably in the form of a metal, preferably copper, plate,
the assembly of the housing elements superposed in this way, with the aid, where appropriate, of screws engaged into the nuts, and
the establishing of electrical contacts by soldering, notably by subjecting the assembly to a temperature that causes a soldering paste present between the surfaces to be soldered to melt.

The method may comprise the replacement of one shim with another of different shape, adapted to a different chip model.

A further subject of the invention is the assembly guide as such, and the assembly guide and the assembly of the components of the module that are intended to be assembled with the aid of the guide.

### BRIEF DESCRIPTION OF THE DRAWINGS

The invention will be able to be better understood upon reading the following detailed description of non-limiting exemplary implementations thereof, and upon examining the appended drawing, in which:

FIG. 1 is a perspective view of an example of a power module according to the invention,

FIG. 2 is an exploded view of the module in FIG. 1, and of the assembly guide,

FIG. 3 shows the assembly guide in isolation,

FIG. 4 illustrates the introduction of the nuts into the bottom of the main cutout of the assembly guide,

FIG. 5 illustrates the introduction of the first copper plate into the main cutout of the assembly guide,

FIG. 6 illustrates the introduction of the first housing element into the main cutout of the assembly guide,

FIG. 7 illustrates the introduction of the first chip into the cutout defined by the first housing element,

FIG. 8 illustrates the introduction of the shim onto the first chip,

FIG. 9 illustrates the introduction of the first connection elements,

FIG. 10 illustrates the introduction of the intermediate housing element,

FIG. 11 illustrates the introduction of the capacitor,

FIG. 12 illustrates the introduction of the other connection elements,

FIG. 13 illustrates the introduction of the upper housing element,

FIG. 14 illustrates the introduction of the second chip into the cutout of the upper housing element,

FIG. 15 illustrates the introduction of the second copper plate onto the second chip,

FIG. 16 illustrates the introduction of retaining screws,

FIG. 17 shows the shim in isolation,

FIG. 18 is a view similar to FIG. 7, in the case of the use of a different chip,

FIG. 19 shows an example of a shim adapted to the chip in FIG. 18 in isolation,

FIG. 20 is a perspective view of the shim in FIG. 19 from another viewing angle,

FIG. 21 is a view similar to FIG. 7, in the case of the use of a different chip,

FIG. 22 shows an example of a shim adapted to the chip in FIG. 21 in isolation,

FIG. 23 is a perspective view of the shim in FIG. 22 from another viewing angle, and

FIG. 24 illustrates the establishing of the electrical connections between the connection elements and the chip.

### DETAILED DESCRIPTION

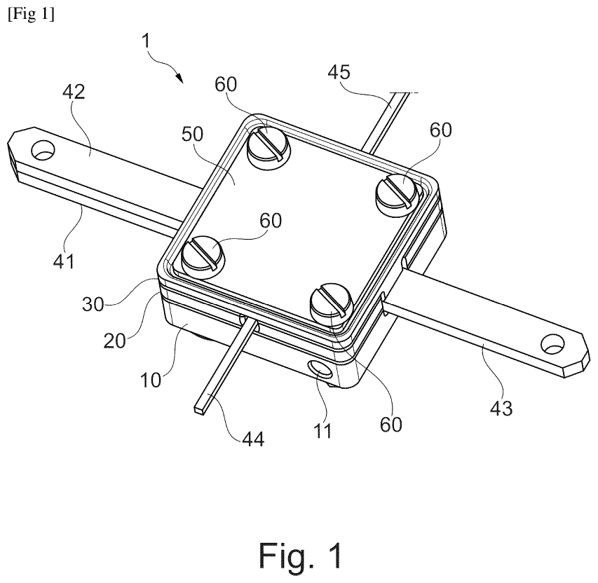

The power module 1 shown in FIG. 1 comprises three superposed housing elements, namely a first, lower housing element 10, a second, intermediate housing element 20, and a third, upper housing element 30.

The module 1 also comprises connection elements, namely, in the example illustrated, metal tabs 41 and 42 extending opposite a first side of the module 1, a metal tab 43 extending on the opposite side therefrom, and opposite metal tabs 44 and 45 extending from the two other sides.

The module 1 may comprise, as illustrated, on its main faces, heat transfer plates, of which one 50 is visible in FIG. 1.

The different housing elements and the heat transfer plates may be retained by screws 60, as illustrated.

The module 1 is shown in FIG. 1 prior to a potential encapsulation.

At least one of the housing elements, for example the lower element 10, may comprise an opening 11 for injecting a filling insulating resin, referred to as “underfiller”.

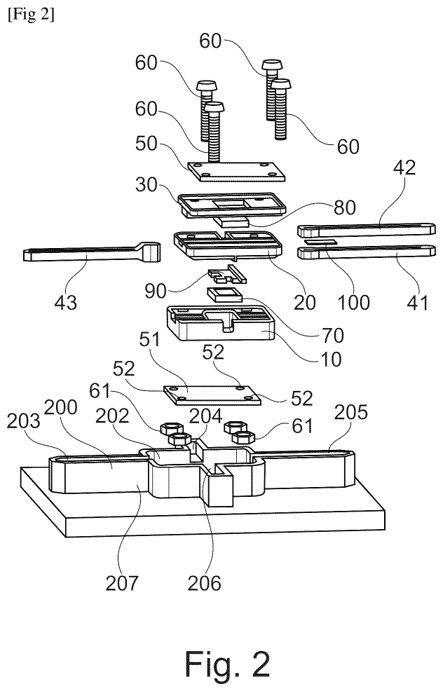

If reference is made to FIG. 2, it can be seen that the module 1 comprises first 70 and second 80 electronic chips, and at least one shim 90.

What can also be seen in this figure is the lower heat transfer plate 51 and the nuts 61 into which the screws 60 come to engage.

A capacitor 100 may be disposed between the connection elements 41 and 42.

The chips 80 and 90 are for example power transistors, for example based on GaN; for example, the source of one is connected to the drain of the other by a centre tap, and the connection elements 41 and 42 are for example connected to the drain of one and to the source of the other, whereas the connection element 43 is connected to the centre tap. The connection elements 44 and 45 are for example connected to the gates of these transistors.

The capacitor 100 is for example a decoupling capacitor, the value of which is for example several nF.

FIG. 2 also shows an assembly guide 200 used during the manufacture of the module 1.

This guide 200 is for example made of plastics material and can be produced with relatively rough manufacturing tolerances by injection moulding.

It may comprise a horizontal base 201 topped by a vertical wall 207 which defines a main cutout 202 and four secondary cutouts 203 to 206, which are disposed around the main cutout 202 in the same way as the connection elements on the module.

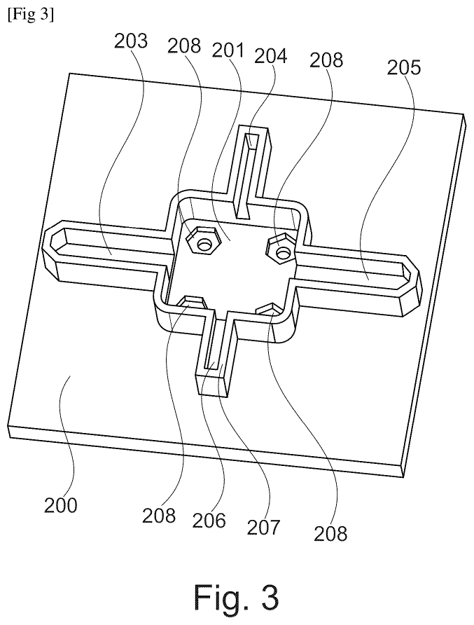

The assembly guide has been shown in isolation in FIG. 3. It can be seen that the bottom of the main cutout 201 comprises impressions 208 for receiving nuts 61.

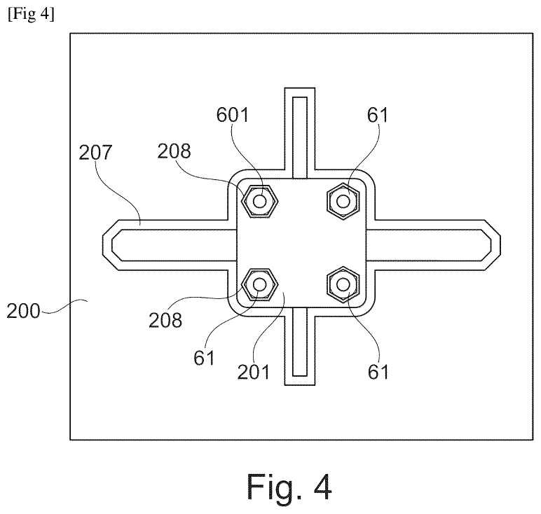

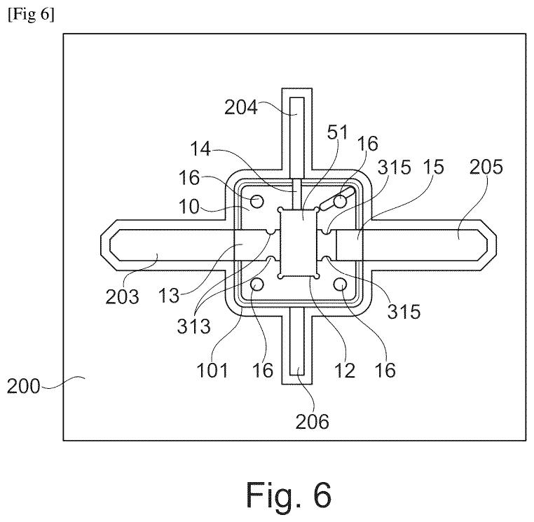

A further description, referring to FIGS. 4 to 17, will now be given of the various elements that make up the module and of an example of a method for manufacturing said module.

When screws are used to retain the assembled housing elements, the manufacturing method may start by disposing the nuts 61 in the corresponding impressions 208, as illustrated in FIG. 4.

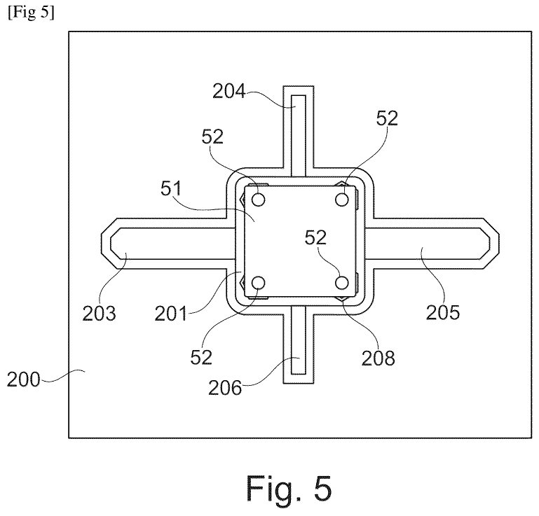

Then, as illustrated in FIG. 5, the lower plate 51 is placed in the bottom of the cutout 201; this plate comprises holes 52 for the passage of the screws 60.

In the example considered, the plate 51 is made of copper, but it can be replaced with any suitable dissipator, for example made of another metal or made of a heat-conducting ceramic.

The different elements that make up the module can be placed by any suitable tool, notably a conventional “pick and place” tool.

The lower housing element 10 can then be deposited in the cutout 101.

This element 10 comprises a first central through-cutout 12, intended to receive the first chip 70, and cutouts 13, 14 and 15 that do not pass all the way through for respectively receiving the connection elements 41, 45 and 43. These cutouts 13, 14 and 15 open out into the cutouts 203, 204 and 205, respectively, of the guide 200. Holes 16 are provided for the passage of the screws 60.

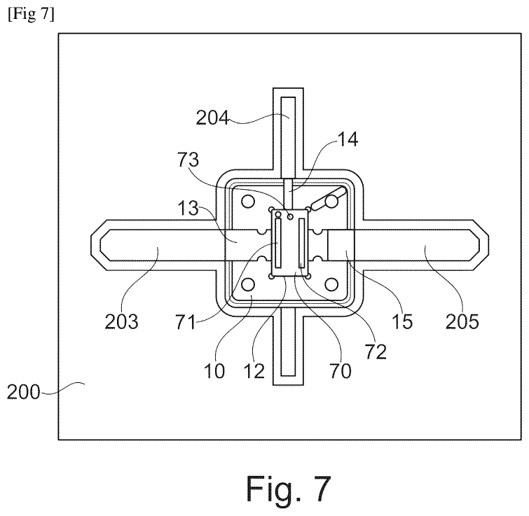

FIG. 7 shows the guide 200 after the chip 70 has been placed in the cutout 12.

In this example, the chip 70 has a parallelepipedal overall shape, the contour of which in top view corresponds substantially to that of the cutout 12.

The chip 70 may have electrical contacts 71, 72 and 73 on its inner face.

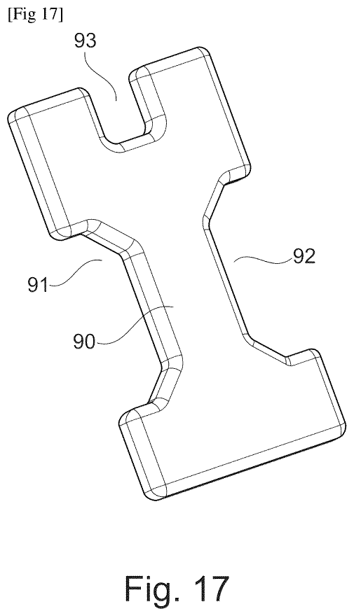

The shim 90 has been shown in isolation in FIG. 17.

Said shim has a length and width that are adapted for the positioning thereof in the cutout 12 with a small clearance.

It can be made of any electrical insulating material compatible with the conditions of use, for example a ceramic or a polymeric material.

The shim 90 has two lateral openings 91 and 92 and an opening 93 at the end, in the form of notches.

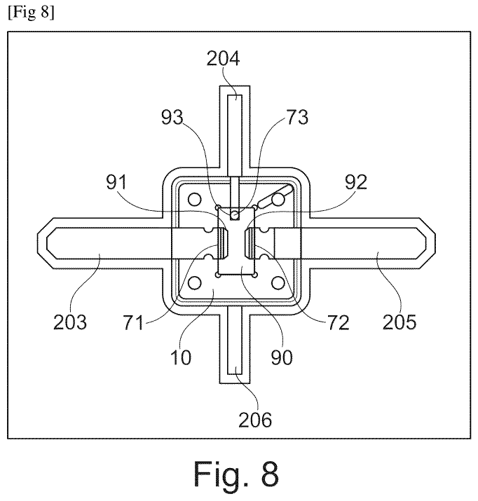

Once the shim 90 has been placed on the chip 70, as illustrated in FIG. 8, the contacts 71, 72 and 73 remain accessible through the openings 91, 92 and 93, respectively.

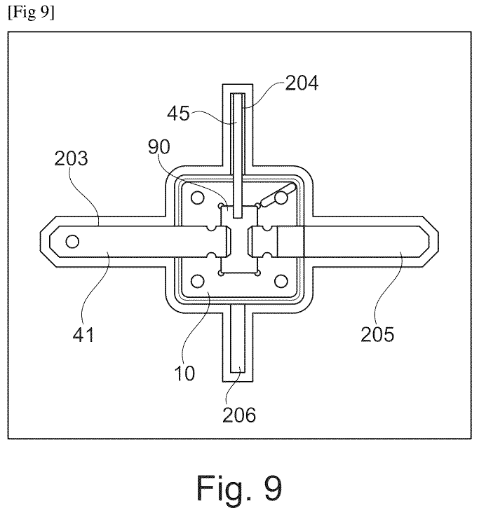

The connection elements 41 and 45 can then be placed in the cutouts 203 and 204, respectively, coming to partially cover the contacts 71 and 73, as illustrated in FIG. 9. A soldering paste can be deposited at the interface between the contacts of the chip and the connection elements, for the purpose of a subsequent soldering operation.

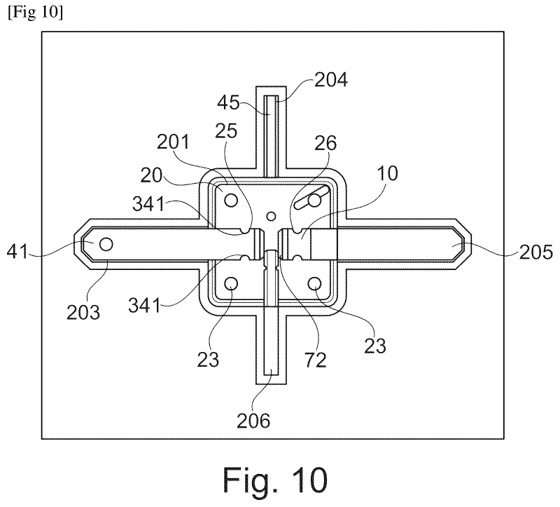

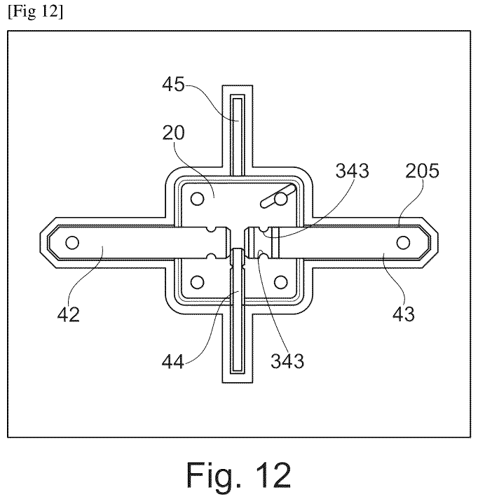

It may be useful to form, in the cutouts 13 and 15, reliefs 313 and 315 intended to cooperate with corresponding reliefs of the connection elements received in these cutouts, so as to improve the positioning and the retention of the connection elements during the assembly operations. The reliefs 313 or 315 are, for example, in the form of bosses facing each other, and the connection element then has two notches 341 or 343, visible in FIGS. 10 and 12, respectively, which are intended to fit on these bosses.

Cooperating reliefs in the form of bosses and notches between the housing elements and the connection elements may be present for each of the five connection elements of the module, as is visible in the figures, and will not be described in detail each time hereinafter.

Then, the intermediate housing element 20 can be introduced into the cutout 201 in order to cover the components that are already present.

The element 20 has holes 23 for the passage of the screws 60, and openings 24, 25 and 26 intended to receive the connection elements 44, 42 and 43, respectively.

The opening 26 provides access to the contact 72 of the chip 70.

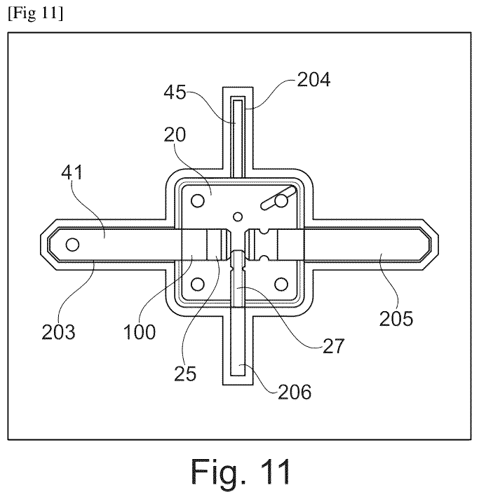

In the step illustrated in FIG. 11, the capacitor 100 is placed on the connection element 41, in the opening 25.

The connection element 42 can then be introduced in order to cover the capacitor 100, as illustrated in FIG. 12, and the capacitor 100 serves as a spacer between the connection elements 41 and 42.

The connection element 43 is introduced on the opposite side.

When necessary, soldering paste is disposed between the components to be soldered, notably between the capacitor 100 and the connection elements 41 and 42 and between the connection element 43 and the corresponding contact 72 of the chip 70.

The connection element 44 is introduced into a corresponding cutout 27 of the housing element 20.

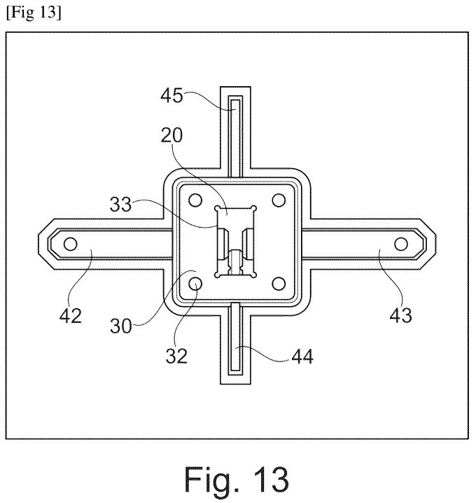

Then, the housing element 30 is introduced onto the previously installed connection elements, as illustrated in FIG. 13.

The housing element 30 has a central opening 33, for example of rectangular shape, as illustrated. This opening 33 provides access to the connection elements 42, 43 and 44.

The housing element 30 comprises holes 32 for the passage of the screws 60.

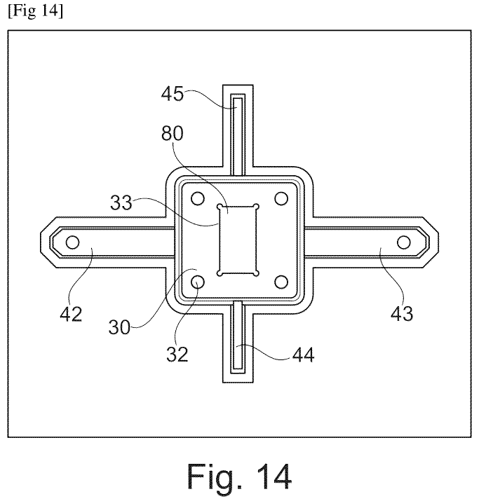

The second chip 80 can then be disposed in the cutout 33, as illustrated in FIG. 14.

This chip 80 has contacts on its face facing towards the interior, which are positioned facing connection elements 42, 43 and 44, respectively.

A soldering paste can be disposed at the interface between the contacts of the chip 80 and the connection elements, so as to enable the soldering during a subsequent heating step.

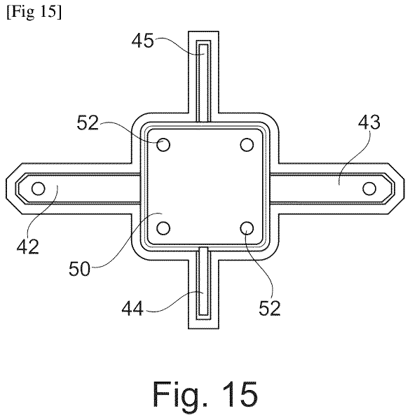

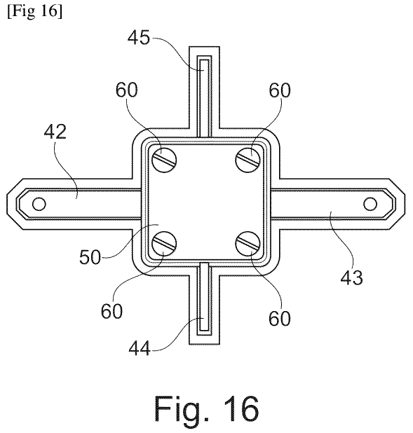

Once the chip 80 is in place, a second heat transfer plate 50, for example made of copper, can be placed against the chip 80, as illustrated in FIG. 15, this plate 50 being for example identical to the first plate 51 and comprising, just like the latter, holes for the passage of the screws 60. These screws can then be mounted and engaged on the nuts 61 present in the bottom of the main cutout 202 of the guide 200, as illustrated in FIG. 16.

Once the screws 60 have been tightened, the assembly can then be taken out of the guide 200 and heated in an oven at a temperature suitable for melting the soldering paste and for producing soldered joints to be effected between the different components of the module.

After soldering, a filling resin can be injected through the orifice 11 and the assembly can be encapsulated, if necessary, in an encapsulation resin, leaving the connection elements accessible, and where appropriate the copper plates when the thermal coupling to a radiator is intended.

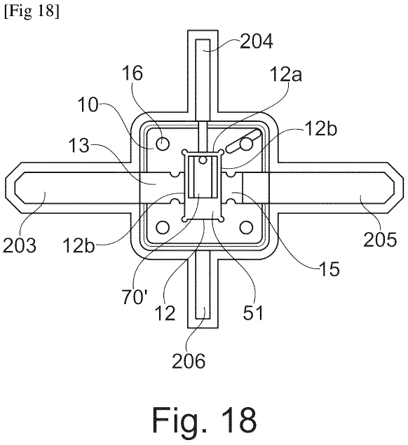

The use of a shim 90 is advantageous because it makes it possible to replace the first chip 70 with a second 70′ of different format, without needing to modify the lower housing element 10, as illustrated in FIG. 18.

In the example illustrated, the chip 70′ has dimensions that are smaller than those of the chip 70.

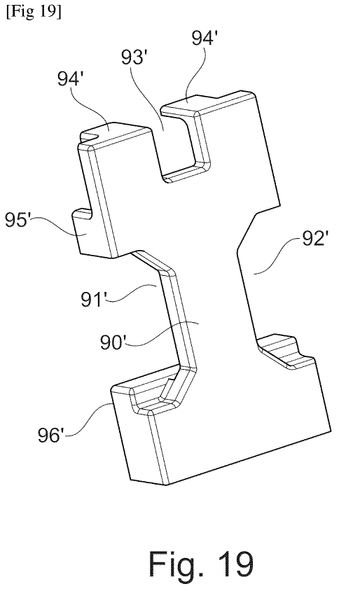

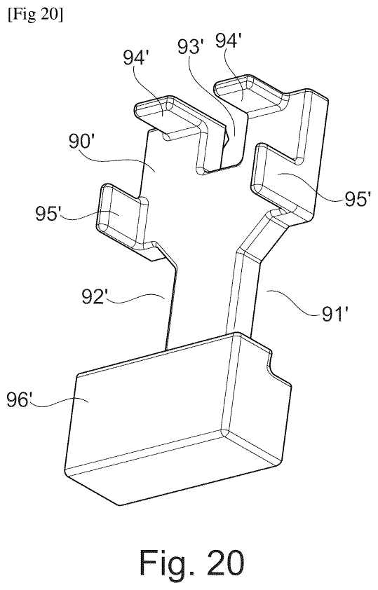

The shim 90 can be replaced with a shim 90′ shown in isolation in FIGS. 19 and 20, having openings 91′, 92′ and 93′ like the shim 90, and, on one face, protruding portions intended to engage into the space provided between the chip 70′ and the edge of the cutout 12.

In the example considered, the shim 90′ thus comprises two end tabs 94′ situated on either side of the opening 93′, which are intended to engage between the chip 70′ and the short side 12a of the cutout 12.

The shim 90′ also comprises two lateral tabs 95′ which are each configured to be inserted between a long side of the chip 70′ and a long side 12b of the cutout.

The shim 90′ comprises, on the opposite side from the tabs 94′, a stub 96′ arranged so as to engage between the chip 70′ and the other short side 12a of the cutout 12.

Thus, the shim 90′ is positioned precisely in the cutout 12, due to the outer dimensions thereof, whilst retaining the chip 70′ precisely within the cutout 12, at a location suitable for establishing electrical connections with the associated connection elements.

When the chip model used does not have the same electrical contacts as those of the other chips used, the shim can comprise at least one conductive track for electrically connecting at least one corresponding contact of the chip to an associated connection element.

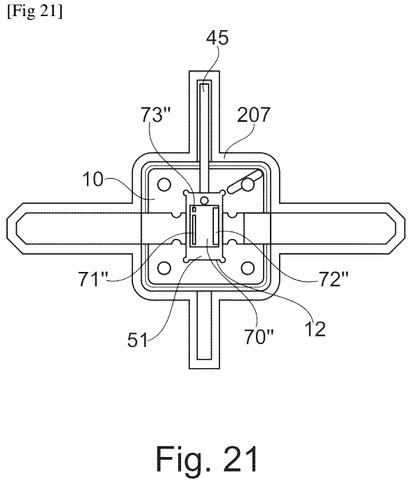

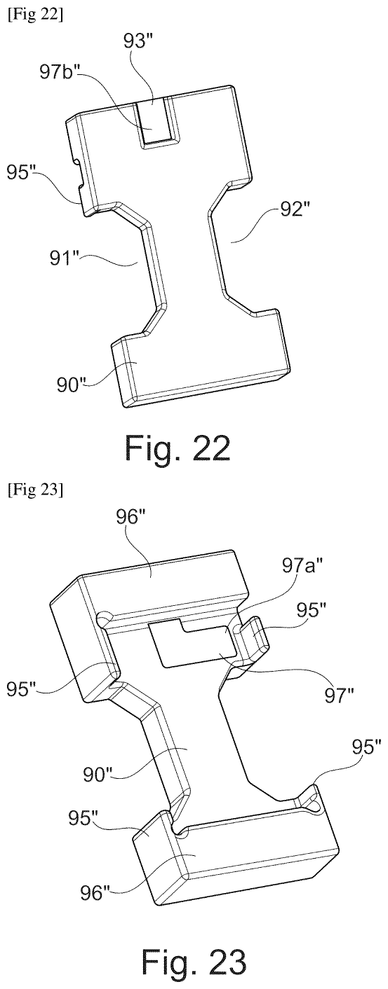

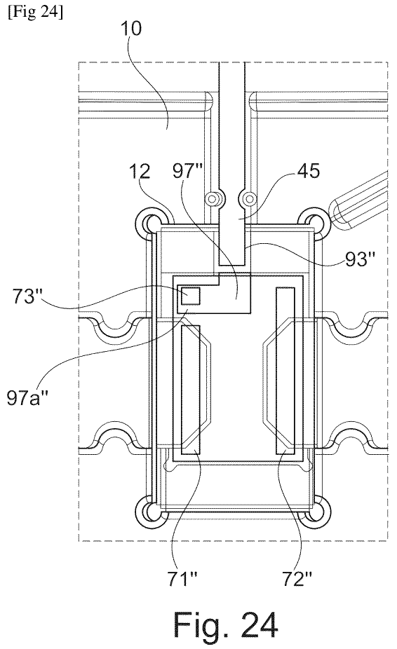

By way of example, FIGS. 21 to 24 illustrate such a situation.

FIG. 21 shows a chip variant 70″ which is not only smaller than the chip 70, just like the chip 70′, but also has contacts 71″, 72″ and 73″ that are disposed differently, notably with a contact 73″ offset laterally relative to the connection element 45. In FIG. 21, the connection element has been shown to illustrate this offset, even though it is introduced subsequently.

The shim 90″ has, like the other shims 90 and 90′, cutouts 91″, 92″ and 93″ for respectively receiving the ends of the connection elements 41, 43 and 45.

The shim 90″ comprises reliefs for positioning the chip 70″ in the cutout 12, for example lateral tabs 95″ and end portions 96″.

Some of the tabs 95″ may extend up to the adjacent end portion.

The shim 90″ comprises a conductive track 97″, for example in the form of a bend as illustrated, positioned so as to be superposed by an end 97a″ with the contact 73″. The track 97″ extends, at the other end 97b″, into the bottom of the cutout 93″, in order to be connected to the connection element 45.

The track 97″ is for example integrated into the shim 90″ during the manufacturing process for said shim. This may be a metal part inserted into the ceramic or produced by injection moulding or screen printing.

The housing elements 10, 20 and 30, and the shim 90, 90′ or 90″, may be manufactured in such a way as to already exist during the assembly, made of any electrical insulating material(s) compatible with the desired use, for example made of a ceramic, notably by a 3D printing or sintering method. The material is selected in order to thermally withstand the soldering operation for the contacts, the heat released during normal use of the module, and the operating environment; thus the assembly can withstand a temperature of at least 150° C. for example.

To produce the electrical connections, a soldering paste may be used, the invention not being limited to a particular technique for establishing the electrical connections.

The invention is not limited to the examples that have just been described.

For example, the module may comprise more than one shim, and it is in particular possible to use a second shim to enable the mounting, like the second chip, of chips of different sizes and/or implementation of contacts; where appropriate, the intermediate housing element is also modified to facilitate the adaptation of different chip models.

It is also possible to assemble more than two chips within a module, and to use one or more shims that enable the use of different chip models.

The cutouts of the housing elements that are intended to receive the chips may have a shape other than rectangular, for example square or other. It is also possible to have a plurality of cutouts intended to receive respective chips in the same housing element, and to have one or more shims associated with these chips.

Some connection elements, for example the elements 44 and 45 connected to the gates of the transistors, may exit on the same side of the housing to facilitate the control of the module.

1. A power module comprising
a first housing element having a first cutout for receiving a first chip,
a first chip at least partially received in the first cutout, having electrical contacts,
connection elements electrically connected to the electrical contacts of the first chip,
at least one insulating shim at least partially disposed in the first cutout so as to at least partially cover said chip, having at least one opening providing access to at least one electrical contact of the chip through the shim and/or at least one track ensuring the connection to one of the connection elements and/or a potential capacitor.

2. A power module according to claim 1, comprising:
a second housing element having a second cutout for receiving a second chip,
a third housing element disposed between the first and second housing elements, having at least a third cutout for receiving a capacitor,
a second chip at least partially received in the second cutout, having electrical contacts,
connection elements electrically connected to the electrical contacts of the second chip,
at least one capacitor at least partially received in the third cutout and electrically connected to at least one of the chips and/or to the connection elements.

3. The power module according to claim 1, the shim having, at an edge, at least one lateral opening into which a corresponding connection element electrically connected to a contact of the chip engages.

4. The module according to claim 3, the shim having, at two opposite longitudinal edges, two respective lateral openings into which two corresponding connection elements electrically connected to two respective contacts of the chip engage.

5. The module according to claim 3, the connection element or elements being soldered to the corresponding contact(s) of the chip.

6. The power module according to claim 5, the shim having, at an edge substantially perpendicular to the longitudinal edges, an additional opening into which an additional connection element electrically connected to a respective contact of the chip engages.

7. The power module according to claim 6, the additional connection element being soldered to a corresponding contact of the chip.

8. The module according to claim 6, the shim bearing an electrical track soldered to a corresponding contact of the chip, and the additional connection element being soldered to the track.

9. The module according to claim 1, the shim being longer than the chip at the contact thereof, and having at least one portion engaged into the cutout between the chip and the housing element defining the cutout receiving the chip in contact with the shim.

10. The module according to claim 9, the shim being interposed on at least three sides between the chip and the housing element defining the cutout receiving the chip in contact with the shim.

11. The module according to claim 1, the shim having a face that is substantially coplanar with a face of the housing element defining the cutout receiving the chip in contact with the shim.

12. The module according to claim 1, the intermediate housing element having cutouts for receiving connection elements positioned so as to make it possible to superpose the latter with electrical contacts of the second chip.

13. The module according to claim 1, the housing elements being passed through by holes allowing the passage of retaining members for retaining the housing elements in the assembled state.

14. The module according to claim 1, comprising at least one heat transfer element in contact with an outer face of a chip.

15. An array of power modules, comprising at least a first and a second module according to claim 1, at least one of the chips of the first module being different from a corresponding chip of the other module, the two modules comprising different shims and identical housing elements.

16. The array according to claim 15, the connection elements being identical.

17. A method for manufacturing a power module according to claim 1, this module comprising:
a lower housing element having the first cutout for receiving a first chip,
the first chip at least partially received in the first cutout, having electrical contacts, the method comprising the steps of:
covering the chip present in the first cutout with an insulating shim, this shim defining at least one opening which is superposed with at least one electrical contact of the chip or having an electrical track to be connected to an electrical contact of the chip, the electrical track leading to an opening in the shim that is intended to receive a connection element.

18. The method according to claim 17, the shim being selected from among a plurality of pre-existing shims depending on the type of chip used, all of these shims being adapted to be positioned in said cutout of the lower housing element, the shims preferably being selected from among a set of shims comprising:
a shim having two opposite openings on its long sides and one opening on a short side, the dimensions of the shim corresponding substantially to those of the cutout of the first housing element,
a shim having two opposite openings on its long sides and one opening on a short side, the dimensions of the shim corresponding substantially to those of the cutout of the first housing element, the shim having, on its face facing towards the chip, opposite lateral returns intended to each be interposed between a long side of the chip and a corresponding edge of the first cutout, and at least one end tab intended to be interposed between a short side of the chip and a corresponding edge of the first cutout, and at least one portion intended to engage into the cutout between the chip and the lower housing element, on the opposite side from the end tab;
a shim having two opposite openings on its long sides and one opening on a short side, the dimensions of the shim corresponding substantially to those of the cutout of the first housing element, the shim having at least two portions each intended to be interposed between a short side of the shim and a corresponding edge of the cutout, the shim having, on its face facing towards the chip, opposite lateral returns intended to each be interposed between a long side of the chip and a corresponding edge of the first cutout, the shim also having at least one conductive track arranged to be at least partially superposed with a contact of the chip and with a connection element.

19. The method according to claim 17, the method comprising the introduction:
of an upper housing element having a second cutout for receiving a second chip,
of an intermediate housing element disposed between the upper and lower elements, having at least a third cutout for receiving a capacitor,
of a second chip at least partially received in the second cutout, having electrical contacts,
of connection elements electrically connected to the electrical contacts of the chips,
of at least one capacitor at least partially received in the third cutout and electrically connected to at least one of the chips and/or to the connection elements.

20. The method according to claim 17, comprising the use of an assembly guide having at least a main cutout adapted to receive at least the lower housing element.

21. The method according to claim 19, the assembly guide having secondary cutouts adapted to receive the connection elements.

22. The method according to claim 20, the main cutout having a bottom comprising at least one impression for receiving a nut or a screw head, the method comprising the positioning of at least one nut or a screw head in the main cutout before the first housing element, in particular, is introduced into said main cutout.

23. The method according to claim 20, comprising the positioning of a heat transfer element plate in the bottom of the main cutout.

24. The method according to claim 17, comprising the following successive steps:
the optional introduction, in the main cutout of the assembly guide, of nuts into the corresponding cutouts potentially provided at the bottom of said main cutout,
the introduction of a heat transfer element into the main cutout, covering the nuts where appropriate,
the introduction of the lower housing element onto the metal transfer element,
the introduction of the first chip into the cutout defined by the first housing element,
the introduction of the shim onto the first chip,
the introduction of connection elements that come to cover at least one contact of the chip and/or a track to be electrically connected to a contact of the chip,
the introduction of the intermediate housing element,
the introduction of the capacitor onto one of the connection elements, in a corresponding cutout of the intermediate housing element, this capacitor having a first electrical contact facing the connection element on which it is deposited,
the introduction of at least one other connection element extending at least partially facing a second electrical contact of the capacitor,
the introduction of the upper housing element onto the assembly present in the main cutout of the assembly guide,
the introduction of the second chip into the cutout of the upper housing element,
the introduction of a second heat transfer element plate,
the assembly of the housing elements superposed in this way, with the aid, where appropriate, of screws engaged into the nuts,
the establishing of electrical contacts by soldering.
